(19) United States
(12) Patent Application Publication
(10) Pub. No.: US 2016/0301414 A1
(43) Pub. Date: Oct. 13, 2016

(54) Dynamic Interconnect with Partitioning on Emulation and Protyping Platforms

(71) Applicant: INTEL CORPORATION, Santa Clara, CA (US)

(72) Inventors: Franz-Wilhelm Olbrich, Braunschweig (DE); Ralf Plate, Lahstedt (DE); Thorsten Mattner, Hemmingen (DE); Heiko Woelk, Uelzen (DE)

(21) Appl. No.: 15/032,465

(22) PCT Filed: Dec. 28, 2013
(86) PCT No.: PCT/US2013/078149

§ 371 Date: Apr. 27, 2016

(51) Int. Cl. H03K 19/177; G06F 13/40; G06F 17/50; H03K 19/0175

(52) U.S. Cl. CPC H03K 19/17744; H03K 19/0175; G06F 13/4059; G06F 17/5054

(57) ABSTRACT

A dynamic interconnect is described herein. The dynamic interconnect includes a transmit module, a receive module, and a multiplexer. Signal changes are detected in a group of transmit channels, and in response to the signal change an output of the multiplexer is switched to the channel where the change occurs.

### TECHNICAL FIELD

The present techniques relate generally to time division data multiplexing and transmission. More specifically, the present techniques relate to a dynamic interconnect with frequency aware capabilities.

### BACKGROUND ART

The capacities of field programmable gate arrays (FPGAs) has increased dramatically, while the input/output (I/O) pin count of the FPGAs has remained stable. In order to accurately prototype complex chip designs, several FPGAs may be linked to emulate the chip design. Emulating chip designs using FPGAs enables designers to ensure the chip design functions as intended. Using a single FPGA is desired, however a single FPGA may not have enough I/O pins to emulate the design. By contrast, using several FPGAs can result in poor speed of the prototype.

### BRIEF DESCRIPTION OF THE DRAWINGS

FIG. 1 is an illustration of a dynamic interconnect including a transmit module and a receive module using four transmit channels;

FIG. 2 illustrates the timing for signal change detection and changing the transmission order;

FIG. 3 is a block diagram of an application with channels running on e first partition and a second partition;

FIG. 4 is a process flow diagram illustrating a method for a runtime dynamic multiplexing scheme;

FIG. 5 is a process flow diagram illustrating a method for a frequency aware dynamic multiplexing scheme; and

FIG. 6 an embodiment of a system on-chip (SOC) design in accordance with the inventions is depicted.

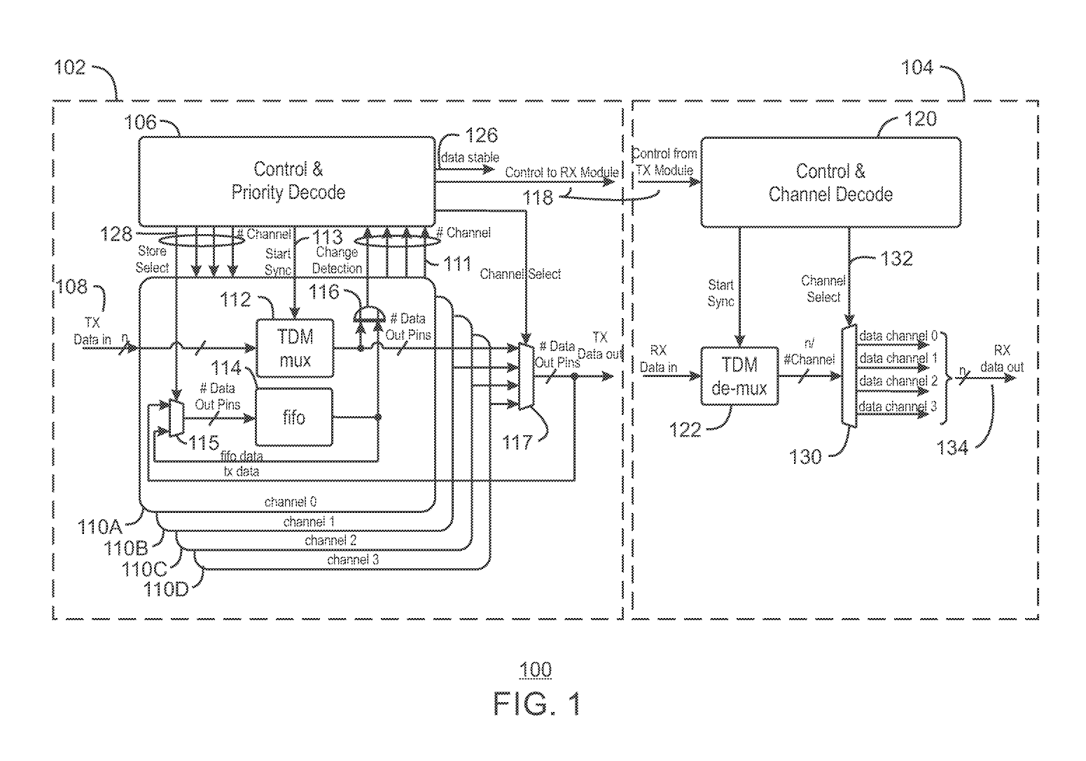

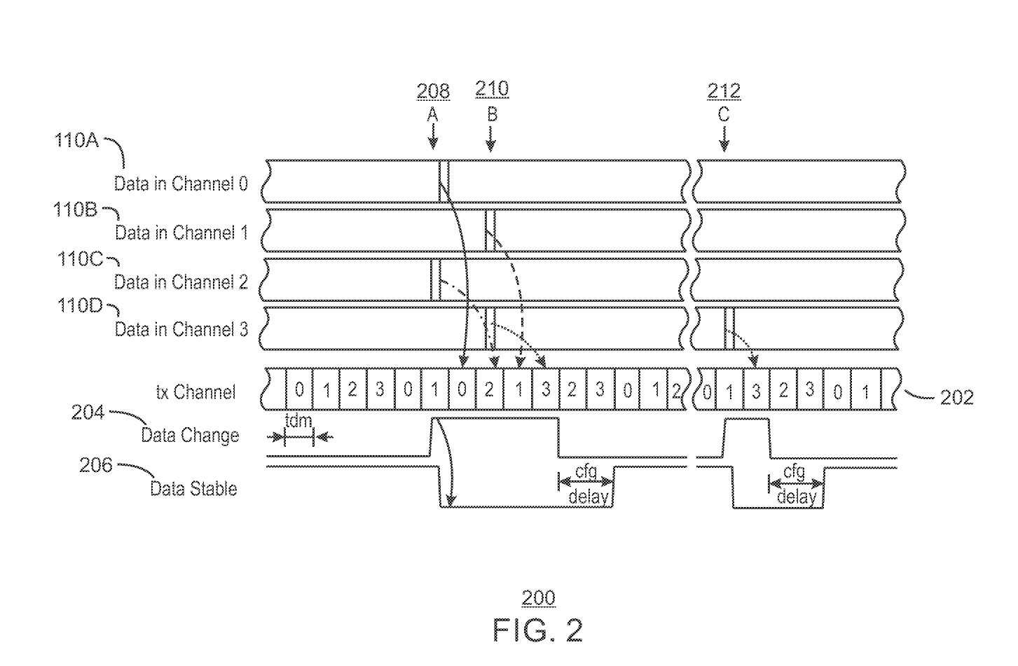

The same numbers are used throughout the disclosure and the figures to reference like components and features. Numbers in the 100 series refer to features originally found in FIG. 1; numbers in the 200 series refer to features originally found in FIG. 2; and so on.

### DESCRIPTION OF THE EMBODIMENTS

The capacities of FPGAs increased dramatically over the last years whereas the I/O pin count remains stable. For FPGA based emulation or prototyping platforms, the increasing gap between capacity and number of I/O pins becomes more and more critical. A lack of I/O pins can introduce bottlenecks in data transmission for designs which are partitioned to multiple FPGAs.

Embodiments described herein are directed toward a dynamic interconnect with partitioning on emulation and prototyping platforms. In some cases, runtime time division multiplexing (TMD) scheme will enable the transmission of signals between two devices more effectively by using a runtime dynamic multiplexing scheme. The devices can be FGPAs. Through the runtime scheme. the required transmission time for a time division multiplexed data connection is optimized by grouping transmit signals into parallel compare units and assigning high transmit priority to groups in which signal values have changed. The sender can flag the signal change to the receiving chip, and the receiving chip can continue its normal operation after the change signal is de-asserted. Moreover, the receiving chip does not wait on the reception of unchanged signals.

The present techniques also uses switching characteristics of the different signal groups into account and selects different interconnect implementations for each group to better utilize the available physical links of the hardware platform. As used herein, switching characteristics refers to the frequency of signal changes. Moreover, as used herein interconnect implementations may include, but is not limited to different TDM and a different number of required physical links.

In embodiments, the switching frequency of the signals may be used when calculating the required TDM schema. Signals which are running on the same application frequency can be grouped, and the knowledge of the required frequency and required interconnect width can be used to calculate the best fitting number of physical links for each individual group. Each group is using a fraction of the whole available number of links.

FIG. 1 is an illustration of a dynamic interconnect 100 including a transmit module 102 and a receive module 104 using 4 transmit channels. A dedicated control module 106 selects the channel to be transmitted. In this example the n user signals 108 on the left side are divided into four channels 110A, 110B, 110C, and 110D. Each channel 110A, 110B, 110C, and 110D processes a fixed multiplexing scheme synced by the control module 106.

For each channel 110, such as channel 110A, a TDM multiplexer 112 is compared with the output of a first in, first out buffer 114. Signal changes are detected by comparing the TDM multiplex 112 output against the output of a data first in, first out (FIFO) buffer 114. A start sync signal 113 may be used to start the TDM multiplexer 112 to ensure that each TDM multiplexer for each FPGA has been synced. A counter can be used to as a mechanism to sync the TDM multiplexers. In some cases, the comparison occurs using an XOR operation at reference number 116. The signal change detection at 111 will switch the output to the channel where the change has been detected. This channel will then be selected for at least one complete TDM cycle. If a channel is selected for transmission, the FIFO 114 input data is the actual transmission data. Otherwise, the FIFO 114 output data is fed back to the FIFO input. Accordingly, the FIFO 114 input may select from the old FIFO 114 data or the data transmitted from a multiplexer 117, which is multiplexed at reference number 115. A source select 128 is used to control the multiplexer 115 so that the correct data is passed back to the FIFO 114.

If no signal changes are detected in any channel the transmission order is given by the channel number. For example, the required multiplexing factor for each channel in this example is: TDM=n/4/(#output pins). In any event, the output of each channel is sent to another multiplexer 117. This multiplexer passes the transmit data output to the receive module 104.

A dedicated control bus 118 is transmitted to the receive module 104 flagging the current transmit channel through a control and channel decode block 120. In some cases, the control bus indicates the origination of the data transmitted to the receive block 104 from the multiplexer 117. The receive TDM de-multiplexer module 122 is synced to the transmit module 102 by evaluating the channel information on the control bus 118. In some cases, switching from channel three to zero synchronizes the receive-TDM counter.

A multiplexer 130 is used to demultiplex the channel data received from the transmit module 102. The control and channel decode 120 takes as input a control signal 118 and uses this to select a channel of the multiplexer 130 with a channel select signal 132. The selected channel is then sent as data out of the receive module at reference number 134.

As long as signal changes are detected, the transmit control module 106 will flag this by de-asserting a “data stable” signal 126 to the application design. The data stable indicates that no changes have been detected. After a configuration period, the data stable signal may be reasserted. This signal 126 could be included in the control bus 118 to the receive module 104 as well. By configuring the delay for “data stable” assertion appropriately, the execution of the next application clock cycle could be delayed automatically until the successful transmission of all changing signals to receive side is guaranteed and all signals are stable at receive module output.

In complex prototyping or emulation systems, designs are separated onto multiple FPGAs, as illustrated by the interconnect 100. For a synchronous system, a clock edge is happens after all input signals to storage elements are stable. This could lead to problems when designs cannot be divided at Flip-Flop boundaries. In these cases, path analysis over multiple chips is required to determine the actual fastest clock period for the whole application design, which is determined by the worst case signal path. This path could contain multiple multiplexer and de-multiplexer sections.

Without the dynamic interconnect illustrated in FIG. 1, the design performance is constantly slow based on the calculated worst case signal delay. With a dynamic interconnect, the system performance is faster as the next application clock edge will be enabled dynamically. Only if a signal is changing on the worst case path the performance could drop down to the same value as in a system without using the dynamic interconnect. Even with a signal change on the worst case path, the design could run faster with our invention as long as there are no signal changes in all channels belonging to the same interconnect module.

FIG. 2 illustrates the timing 200 for signal change detection and changing the transmission order. For ease of description, FIG. 2 includes four channels: channel 0 at reference number 110A, channel 1 at reference number 110B, channel 2 at reference number 110C, and channel 3 at reference number 110D. In this example, channel 0 at reference number 110A has the highest priority, channel 1 at reference number 110B has the second highest priority, channel 2 at reference number 110C has the third highest priority, and channel 3 at reference number has the lowest priority. The priority can be assigned based on various design parameters, such as application frequency, a different TDM, a different number of physical required links and the like.

The transmission slots are illustrated at reference number 202. Each slot has a number that indicates the channel schedule for transmission at a certain point in time. The transmission slots are of a TDM period of time length. The data change signal at reference number 204 is low when there is no change in data, and is high while this is a change in transmission data. Further, the data stable signal at reference number 206 is high when the data is stable. The data stable signal at reference number 206 is low when the data is changing, and does not return to high until a period of time has elapsed after the last data change. In some cases, the period of time is referred to as a configuration delay.

Before a data change, a channel scheduler may select channels for transmission according to any algorithm, such as a round robin algorithm. At time “A” at reference number 208, the input of channel two at reference number 110C changes. This change de-asserts the data stable signal at reference number 206 for a configurable time and channel two is marked for transmission in the next slot. The configurable time may be any time period implemented by the design. As noted above, each transmission slot lasts TDM transmit clock cycles. The change is marked as long as the channel causing the change has not been transmitted. Since data of channel zero at reference number 110A changes shortly after channel two at reference number 110C and channel zero at reference number 110A has a higher priority, channel zero at reference number 110A is marked for transmission in the next time slot before channel 2 at reference number 110C. At time “B” at reference number 210, the data of channel one at reference number 110B and channel three at reference number 110D are changing. Channel one at reference number 110B has the higher priority and will be transmitted first, before channel three at reference number 110D. After channel three at reference number 110D is transmitted, the channel scheduler returns to a round robin algorithm, which was interrupted at time “A” and continues by transmitting channel two. The data stable signal will be asserted when the configured time has elapsed after data change de-assertion.

At time “C” at reference number 212, data input at channel three at reference number 110D changes and is scheduled for the next transmission slot. Since there is no other data change, the data stable signal is asserted again after channel three at reference number 110D has been transmitted and the configurable delay has elapsed. Thus, the application design could continue execution much faster than at time “A”.

Through the dynamic interconnect, the number of transmit channels is configurable. Signal value change detection is applied to each channel, and signal transmission is prioritized for channels with changing signals. In some embodiments, a small control bus is used from transmit to receive module. Further, a locking mechanism on transmit side of the interconnect prevents the next application clock edge while signals are changing. Overall, the dynamic interconnect results is a very small overhead on receive side compared to a standard TDM demultiplexer module. Additionally, in some embodiments, in case the transmit data does not change for all channels, the application design could run up to number of channel times faster than a system build up using a fixed TDM scheme.

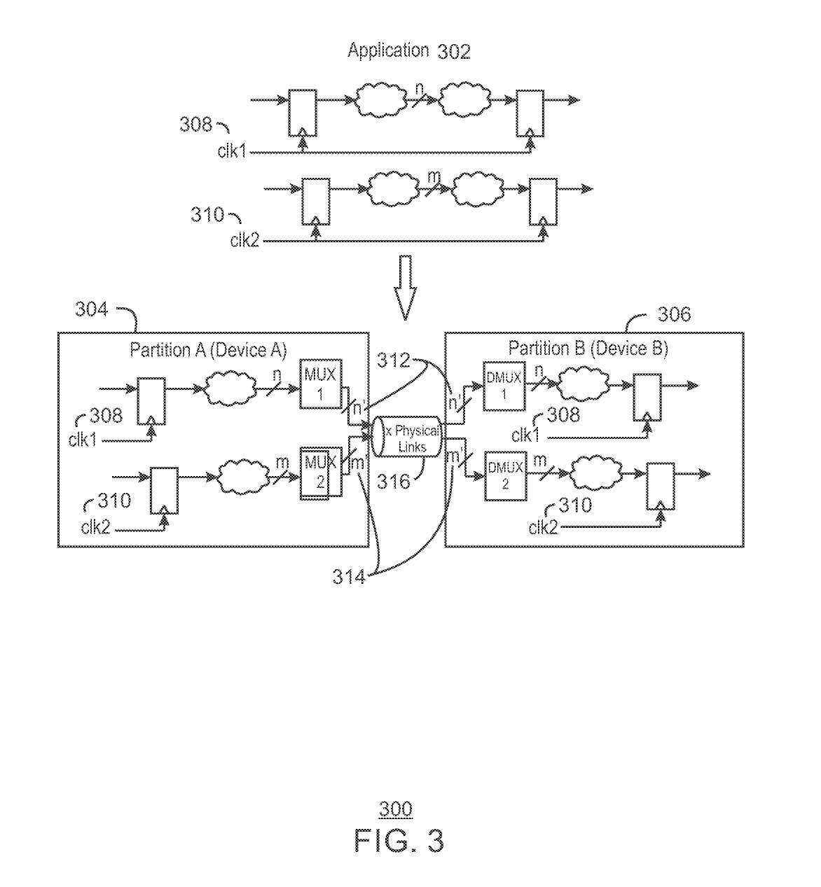

FIG. 3 is a block diagram of an application 302 with channels running on e first partition 304 and a second partition 306. The application 302 is analyzed to determine the different clock domains, and the signals of the application 302 running the different domains are grouped or partitioned according to a respective clock domain. For example, the application includes a first CLK1 domain at reference number 308, and a second CLK2 domain at reference number 310. For ease of description, two clock domains 308 and 310 are illustrated. However, any number of clock domains can be used.

When the signals are partitioned, the total numbers of signals per group is determined. In this example, a group of signals n is at reference number 312, and a group of signals m is at reference number 314. The group of signals n at reference number 312 runs on the first clock domain 308, while the group of signals m at reference number 314 runs of the second clock domain 310.

To calculate an optimal time-division-multiplex (TDM) factor for each of the group of signals n at reference number 312 and the group of signals m at reference number 314, the number of available physical links within the system is required. The optimal TDM may be referred to as fmax, and is the highest frequency of all clocks in the application. In this example the clocks of the application are the first CLK1 domain at reference number 308, and the second CLK2 domain at reference number 310. Moreover the number of physical links is represented between partition 304 and partition 306 at reference number 316.

Based on these parameters, an individual TDM factor for each of the group of signals n at reference number 312 and the group of signals m at reference number 314 can be calculated:

n′=f(n, f₁, fₘₐₓ, x)

m′=f(n, f₂, fₘₐₓ, x),

where n′ is the TDM factor for the group of signals n at reference number 312 and is a function of the group of signals n, the application frequency for a first virtual link running on a physical link f₁, the optimal TDM fₘₐₓ, and the number of available physical links x. Similarly, m′ is the TDM factor for the group of signals at reference number 314 and is a function of the group of signals m, the application frequency for a second virtual link running on a physical link f₂, the optimal TDM fₘₐₓ, and the number of available physical links x.

By calculating individual TDM factors, signal groups which are running on slower application frequencies can use a smaller portion of the available physical link between the partitions, but can compensate this by having a higher TDM factor for their link. This can be done because these links have a higher timing budget to get their signal states across the physical link. On the other hand the signal group with the highest switching frequency should use the smallest TDM factor because this is mainly limiting the emulation performance.

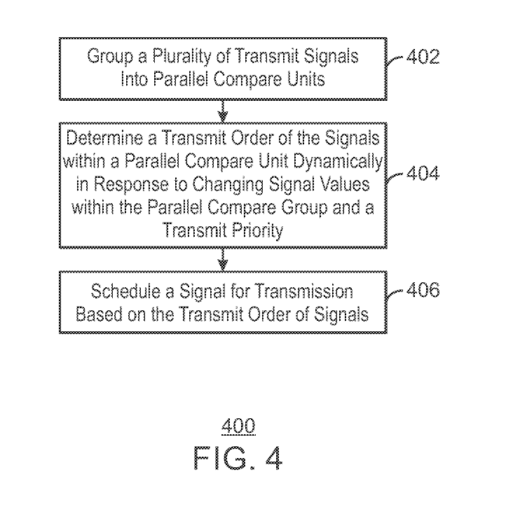

FIG. 4 is a process flow diagram illustrating a method for a runtime dynamic multiplexing scheme. At block 402, a plurality of transmit signals is grouped into parallel compare units. At block 404, a transmit order of the signals is determined within a parallel compare unit dynamically in response to changing signal values within the parallel compare group and a transmit priority. In some cases in response to changing signals, a data stable signal is de-asserted for a period of time. The period of time may be a configurable time delay, implemented according to the particular design of the system. At block 406, a signal for transmission is scheduled based on the transmit order of signals. The signals can be assigned slots of time by a channel scheduler. In some cases, the slots of time lasts a length of a TDM transmit clock cycle.

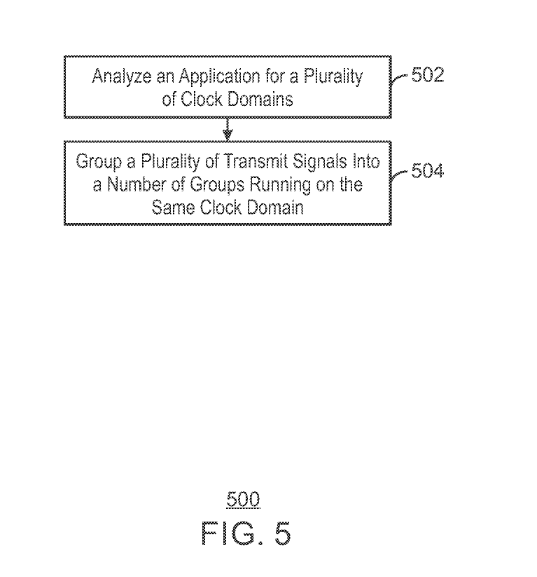

FIG. 5 is a process flow diagram illustrating a method for a frequency aware dynamic multiplexing scheme. At block 502, an application is analyzed for a plurality of clock domains. At block 504, a plurality of transmit signals is grouped into a number of groups running on the same clock domain. The total number of signals the per each group can be calculated using an application frequency, a required frequency, or a required interconnect width, or any combination thereof is used to calculate the number of physical links.

The following table shows some calculated results of a frequency aware dynamic interconnect:

TABLE 1

| | Scenario Nr. | | | | | | |
|---|---|---|---|---|---|---|---|
| | #1 | #2 | #3 | #4 | #5 | #6 | #7 |
| N_{physical} | 240 | 240 | 240 | 240 | 240 | 240 | 240 |
| f₁ | 200 | 300 | 200 | 200 | 200 | 200 | 200 |
| N₁ virtual | 800 | 800 | 160 | 320 | 800 | 800 | 800 |
| f₂ | 100 | 100 | 100 | 100 | 100 | 100 | 100 |
| N₂ virtual | 800 | 800 | 800 | 800 | 160 | 320 | 2640 |
| TDMₛᵢₘₚₗₑ | 7 | 7 | 10 | 17 | 10 | 17 | 114 |
| TDM_{new} | 5 | 5 | 9 | 16 | 7 | 10 | 60 |
| Perf. | 29 | 29 | 10 | 6% | 30 | 41 | 47 |

The first row shows N-physical, which is the total number of available physical wires for a link. As used herein, the link may be a link between two FPGAs. The second row is f1, which represents the application frequency for a first virtual link running on a physical link. The third row is N1-virtual, which designates the number of required virtual wires for the first virtual link running on the physical link. The fourth row is f2, which represents the application frequency for a second virtual link running on the physical link. The fifth row is N2-virtual, which designates the number of required virtual wires for the second virtual link running on the physical link.

The “TDM simple” row shows the resulting TDM using a traditional method of multiplexing if all virtual links are just added and routed via the available physical link. The “TDMnew” row is illustrates the resulting TDM factor with the present techniques described herein, which takes the switching frequency of the virtual links into consideration. The last row shows the performance improvement or increase of the present techniques compared to the traditional method of multiplexing.

The yellow colored fields are indicating which values were changed in comparison to the baseline scenario (#1). As illustrated in the table above, each TDM factor uses more clock cycles to transfer the same amount of data as the new TDM factor according to the techniques described herein. In particular, for the seventh scenario, the new TDM factor transfers data between FPGAs using 60 clock cycles, whereas the traditional TDM transfers the same amount of data in 114 clock cycles. In this manner, the number of clock cycles used to transfer data is reduced by 54 clock cycles, which is nearly a 50% improvement.

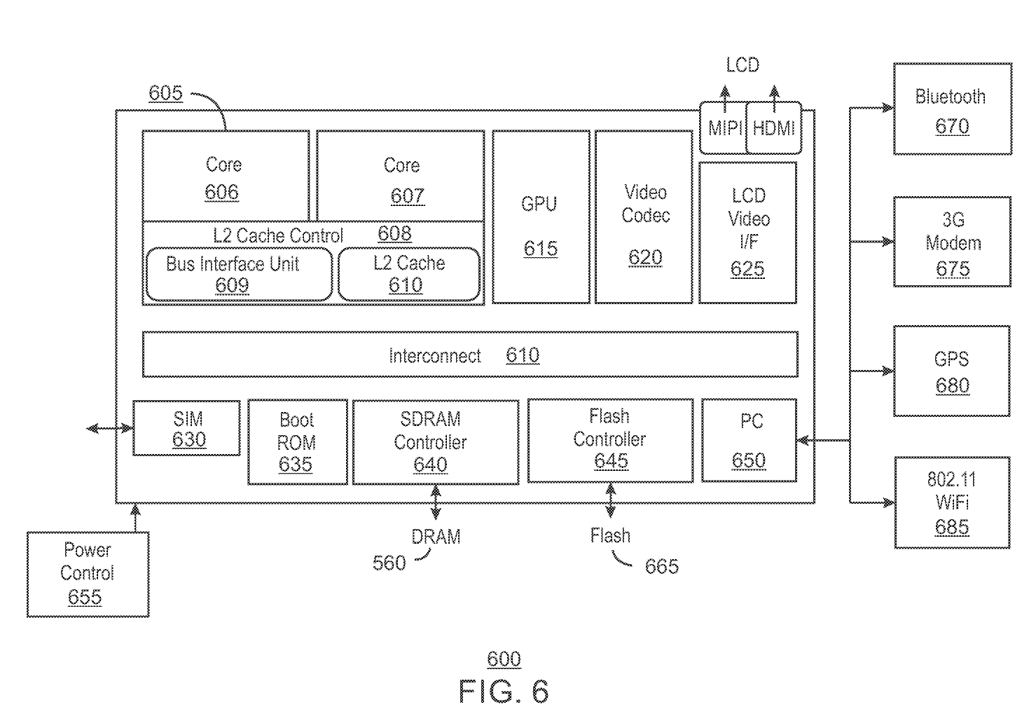

Turning next to FIG. 6, an embodiment of a system on-chip (SOC) design in accordance with the inventions is depicted. As a specific illustrative example, SOC 600 is included in user equipment (UE). In one embodiment, UE refers to any device to be used by an end-user to communicate, such as a hand-held phone, smartphone, tablet, ultra-thin notebook, notebook with broadband adapter, or any other similar communication device. Often a UE connects to a base station or node, which potentially corresponds in nature to a mobile station (MS) in a GSM network.

Here, SOC 600 includes 2 cores—606 and 607. Similar to the discussion above, cores 606 and 607 may conform to an Instruction Set Architecture, such as an Intel® Architecture Core™-based processor, an Advanced Micro Devices, Inc. (AMD) processor, a MIPS-based processor, an ARM-based processor design, or a customer thereof, as well as their licensees or adopters. Cores 606 and 607 are coupled to cache control 608 that is associated with bus interface unit 609 and L2 cache 610 to communicate with other parts of system 600. Interconnect 610 includes an on-chip interconnect, such as an IOSF, AMBA, or other interconnect discussed above, which potentially implements one or more aspects of the described invention.

Interface 610 provides communication channels to the other components, such as a Subscriber Identity Module (SIM) 630 to interface with a SIM card, a boot ROM 635 to hold boot code for execution by cores 606 and 607 to initialize and boot SOC 600, a SDRAM controller 640 to interface with external memory (e.g. DRAM 660), a flash controller 645 to interface with non-volatile memory (e.g. Flash 665), a peripheral control Q1650 (e.g. Serial Peripheral Interface) to interface with peripherals, video codecs 620 and Video interface 625 to display and receive input (e.g. touch enabled input), GPU 615 to perform graphics related computations, etc. Any of these interfaces may incorporate aspects of the invention described herein.

In addition, the system illustrates peripherals for communication, such as a Bluetooth module 670, 3G modem 675, GPS 685, and WiFi 685. Note as stated above, a UE includes a radio for communication. As a result, these peripheral communication modules are not all required. However, in a UE some form a radio for external communication is to be included.

### EXAMPLE 1

A dynamic interconnect is described herein. The dynamic interconnect includes a transmit module, a receive module, and a multiplexer. Signal changes are detected in a group of transmit channels, and in response to the signal changes an output of the multiplexer is switched to the channel where the change occurs.

Signal changes may be detected by comparing the output of the multiplexer with an output of a data first in, first out buffer. The output of the multiplexer may be switched to the channel where the change occurs for at least one TDM cycle. Moreover, in response to no signal change, a transmission order of the coup of transmit channels may be given by a channel number. A dedicated control bus can be transmitted to the receive module, and the dedicated control bus flags the current transmit channel. A TDM demultiplexer of the receive module may be synced to the transmit module by evaluating channel information on the control bus. A transmit control module flags the signal change by de-asserting a data stable signal. Additionally, the data stable signal can be included on a control bus to the receive module. A configuration of the data stable signal can delay a next clock cycle until a changing signals have been received and are stable, and a switching frequency of the transmit channels is analyzed to determine the group of transmit channels.

### EXAMPLE 2

A method for a runtime dynamic multiplexing scheme is described herein. The method includes grouping a plurality of transmit signals into parallel compare units and determining a transmit order of the signals within a parallel compare unit dynamically in response to changing signal values within the parallel compare group and a transmit priority. The method also includes scheduling a signal for transmission based on the transmit order of signals.

A data stable signal may be de-asserted for a period of time in response to changing signal values, and the period of time may be configurable time delay. The signals can be assigned slots for transmission in the transmit order of the signals, and each slot lasts TDM transmit clock cycles. The data stable signal can be asserted after the configured time has elapsed from the changing signal values.

### EXAMPLE 3

A frequency aware dynamic interconnect is described herein. The frequency aware dynamic interconnect includes a transmit module, a receive module, and a multiplexer. The signal changes are detected in a plurality of groups of transmit channels, which are grouped by an application frequency. In response to the signal change, an output of the multiplexer is switched to the channel where the change occurs using a number of physical links.

At least the application frequency, a required frequency, or a required interconnect width, or any combination thereof can be used to calculate the number of physical links. Each group of transmit channels can use a fraction of the whole number of available links. Moreover, a sum of a plurality of virtual links can be routed over the available physical link between different partitions and devices. The plurality of groups of transmit channels can be grouped by an application frequency across a plurality of different clock domains.

### EXAMPLE 4

A method for a frequency aware dynamic multiplexing scheme is described herein. The method includes analyzing an application for a plurality of clock domains and grouping a plurality of transmit signals into a number of groups running on the same clock domain.

The total number of signals per each group can be calculated using an application frequency, a required frequency, or a required interconnect width, or any combination thereof is used to calculate the number of physical links. An optimal time-division-multiplex factor for each frequency group may be calculated based on the number of physical links and other interconnect implementations. Signal groups which are running on slower frequencies can use a smaller portion of the available physical link between the partitions and have a higher time-division-multiplex factor for their link. Signal groups which are running on higher frequencies can use a larger portion of the available physical link between the partitions, and have a lower time-division-multiplex factor for their link.

While the present invention has been described with respect to a limited number of embodiments, those skilled in the art will appreciate numerous modifications and variations there from. It is intended that the appended claims cover all such modifications and variations as fall within the true spirit and scope of this present invention.

A design may go through various stages, from creation to simulation to fabrication. Data representing a design may represent the design in a number of manners. First, as is useful in simulations, the hardware may be represented using a hardware description language or another functional description language. Additionally, a circuit level model with logic and/or transistor gates may be produced at some stages of the design process. Furthermore, most designs, at some stage, reach a level of data representing the physical placement of various devices in the hardware model. In the case where conventional semiconductor fabrication techniques are used, the data representing the hardware model may be the data specifying the presence or absence of various features on different mask layers for masks used to produce the integrated circuit. In any representation of the design, the data may be stored in any form of a machine readable medium. A memory or a magnetic or optical storage such as a disc may be the machine readable medium to store information transmitted via optical or electrical wave modulated or otherwise generated to transmit such information. When an electrical carrier wave indicating or carrying the code or design is transmitted, to the extent that copying, buffering, or re-transmission of the electrical signal is performed, a new copy is made. Thus, a communication provider or a network provider may store on a tangible, machine-readable medium, at least temporarily, an article, such as information encoded into a carrier wave, embodying techniques of embodiments of the present invention.

A module as used herein refers to any combination of hardware, software, and/or firmware. As an example, a module includes hardware, such as a micro-controller, associated with a non-transitory medium to store code adapted to be executed by the micro-controller. Therefore, reference to a module, in one embodiment, refers to the hardware, which is specifically configured to recognize and/or execute the code to be held on a non-transitory medium. Furthermore, in another embodiment, use of a module refers to the non-transitory medium including the code, which is specifically adapted to be executed by the microcontroller to perform predetermined operations. And as can be inferred, in yet another embodiment, the term module (in this example) may refer to the combination of the microcontroller and the non-transitory medium. Often module boundaries that are illustrated as separate commonly vary and potentially overlap. For example, a first and a second module may share hardware, software, firmware, or a combination thereof, while potentially retaining some independent hardware, software, or firmware. In one embodiment, use of the term logic includes hardware, such as transistors, registers, or other hardware, such as programmable logic devices.

Use of the phrase ‘to’ or ‘configured to,’ in one embodiment, refers to arranging, putting together, manufacturing, offering to sell, importing and/or designing an apparatus, hardware, logic, or element to perform a designated or determined task. In this example, an apparatus or element thereof that is not operating is still ‘configured to’ perform a designated task if it is designed, coupled, and/or interconnected to perform said designated task. As a purely illustrative example, a logic gate may provide a 0 or a 1 during operation. But a logic gate ‘configured to’ provide an enable signal to a clock does not include every potential logic gate that may provide a 1 or 0. Instead, the logic gate is one coupled in some manner that during operation the 1 or 0 output is to enable the clock. Note once again that use of the term ‘configured to’ does not require operation, but instead focus on the latent state of an apparatus, hardware, and/or element, where in the latent state the apparatus, hardware, and/or element is designed to perform a particular task when the apparatus, hardware, and/or element is operating.

Furthermore, use of the phrases ‘capable of/to,’ and or ‘operable to,’ in one embodiment, refers to some apparatus, logic, hardware, and/or element designed in such a way to enable use of the apparatus, logic, hardware, and/or element in a specified manner. Note as above that use of to, capable to, or operable to, in one embodiment, refers to the latent state of an apparatus, logic, hardware, and/or element, where the apparatus, logic, hardware, and/or element is not operating but is designed in such a manner to enable use of an apparatus in a specified manner.

A value, as used herein, includes any known representation of a number, a state, a logical state, or a binary logical state. Often, the use of logic levels, logic values, or logical values is also referred to as 1's and 0's, which simply represents binary logic states. For example, a 1 refers to a high logic level and 0 refers to a low logic level. In one embodiment, a storage cell, such as a transistor or flash cell, may be capable of holding a single logical value or multiple logical values. However, other representations of values in computer systems have been used. For example the decimal number ten may also be represented as a binary value of 1010 and a hexadecimal letter A. Therefore, a value includes any representation of information capable of being held in a computer system.

Moreover, states may be represented by values or portions of values. As an example, a first value, such as a logical one, may represent a default or initial state, while a second value, such as a logical zero, may represent a non-default state. In addition, the terms reset and set, in one embodiment, refer to a default and an updated value or state, respectively. For example, a default value potentially includes a high logical value, i.e. reset, while an updated value potentially includes a low logical value, i.e. set. Note that any combination of values may be utilized to represent any number of states.

The embodiments of methods, hardware, software, firmware or code set forth above may be implemented via instructions or code stored on a machine-accessible, machine readable, computer accessible, or computer readable medium which are executable by a processing element. A non-transitory machine-accessible/readable medium includes any mechanism that provides (i.e., stores and/or transmits) information in a form readable by a machine, such as a computer or electronic system. For example, a non-transitory machine-accessible medium includes random-access memory (RAM), such as static RAM (SRAM) or dynamic RAM (DRAM); ROM; magnetic or optical storage medium; flash memory devices; electrical storage devices; optical storage devices; acoustical storage devices; other form of storage devices for holding information received from transitory (propagated) signals (e.g., carrier waves, infrared signals, digital signals); etc, which are to be distinguished from the non-transitory mediums that may receive information there from.

Instructions used to program logic to perform embodiments of the invention may be stored within a memory in the system, such as DRAM, cache, flash memory, or other storage. Furthermore, the instructions can be distributed via a network or by way of other computer readable media. Thus a machine-readable medium may include any mechanism for storing or transmitting information in a form readable by a machine (e.g., a computer), but is not limited to, floppy diskettes, optical disks, Compact Disc, Read-Only Memory (CD-ROMs), and magneto-optical disks, Read-Only Memory (ROMs), Random Access Memory (RAM), Erasable Programmable Read-Only Memory (EPROM), Electrically Erasable Programmable Read-Only Memory (EEPROM), magnetic or optical cards, flash memory, or a tangible, machine-readable storage used in the transmission of information over the Internet via electrical, optical, acoustical or other forms of propagated signals (e.g., carrier waves, infrared signals, digital signals, etc.). Accordingly, the computer-readable medium includes any type of tangible machine-readable medium suitable for storing or transmitting electronic instructions or information in a form readable by a machine (e.g., a computer)

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the invention as set forth in the appended claims. The specification and drawings are, accordingly, to be regarded in an illustrative sense rather than a restrictive sense. Furthermore, the foregoing use of embodiment and other exemplarily language does not necessarily refer to the same embodiment or the same example, but may refer to different and distinct embodiments, as well as potentially the same embodiment.

1-27. (canceled)

28. A dynamic interconnect, comprising
a transmit module;
a receive module; and
a multiplexer, wherein signal changes are detected in a group of transmit channels, and in response to the signal change an output of the multiplexer is switched to the channel where the change occurs.

29. The dynamic interconnect of claim 28, wherein signal changes are detected by comparing the output of the multiplexer with an output of a data first in, first out buffer.

30. The dynamic interconnect of claim 28, wherein the output of the multiplexer is switched to the channel where the change occurs for at least one TDM cycle.

31. The dynamic interconnect of claim 28, wherein in response to no signal change, a transmission order of the coup of transmit channels is given by a channel number.

32. The dynamic interconnect of claim 28, wherein a dedicated control bus is transmitted to the receive module, and the dedicated control bus flags the current transmit channel.

33. The dynamic interconnect of claim 28, wherein a TDM demultiplexer of the receive module is synced to the transmit module by evaluating channel information on a control bus.

34. The dynamic interconnect of claim 28, wherein a transmit control module flags the signal change by de-asserting a data stable signal.

35. The dynamic interconnect of claim 28, wherein a data stable signal is included on a control bus to the receive module.

36. The dynamic interconnect of claim 28, wherein a configuration of a data stable signal delays a next clock cycle until all changing signals have been received and are stable.

37. The dynamic interconnect of claim 28, wherein a switching frequency of the transmit channels is analyzed to determine the group of transmit channels.

38. A method for a runtime dynamic multiplexing scheme, comprising:
grouping a plurality of transmit signals into parallel compare units;
determining a transmit order of the signals within a parallel compare unit dynamically in response to changing signal values within the parallel compare group and a transmit priority; and
scheduling a signal for transmission based on the transmit order of signals.

39. The method of claim 38, comprising de-asserting a data stable signal for a period of time in response to changing signal values.

40. The method of claim 38, wherein a period of time is configurable time delay.

41. The method of claim 38, wherein the signals are assigned slots for transmission in the transmit order of the signals, and each slot lasts TDM transmit clock cycles.

42. The method of claim 38, wherein a data stable signal is asserted after a configured time has elapsed from changing signal values.

43. The method of claim 38, wherein a channel schedule is used to transmit signals before a data change occurs.

44. The method of claim 38, wherein a channel schedule is developed according to an algorithm

45. A frequency aware dynamic interconnect, comprising
a transmit module;
a receive module; and
a multiplexer, wherein signal changes are detected in a plurality of groups of transmit channels which are grouped by an application frequency, and in response to the signal change an output of the multiplexer is switched to the channel where the change occurs using a number of physical links.

46. The frequency aware dynamic interconnect of claim 45, wherein at least the application frequency, a required frequency, or a required interconnect width, or any combination thereof is used to calculate the number of physical links.

47. The frequency aware dynamic interconnect of claim 45, wherein each group of transmit channels uses a fraction of the whole number of available links.

48. The frequency aware dynamic interconnect of claim 45, wherein a sum of a plurality of virtual links are routed over the available physical link between different partitions and devices.

49. The frequency aware dynamic interconnect of claim 45, wherein the plurality of groups of transmit channels is grouped by an application frequency across a plurality of different clock domains.

50. A method for a frequency aware dynamic multiplexing scheme, comprising:
analyzing an application for a plurality of clock domains; and
grouping a plurality of transmit signals into a number of groups running on the same clock domain.

51. The method of claim 50, wherein the total number of signals per each group is calculated using an application frequency, a required frequency, or a required interconnect width, or any combination thereof is used to calculate the number of physical links.

52. The method of claim 50, wherein an optimal time-division-multiplex factor for each frequency group is calculated based on the number of physical links and other interconnect implementations.
